(19) United States
(12) Patent Application Publication
(10) Pub. No.: US 2004/0077160 A1
(43) Pub. Date: Apr. 22, 2004

(54) Method to control dimensions of features on a substrate with an organic anti-reflective coating

(75) Inventor: Kailash N. Singh, San Antonio, TX (US)

Correspondence Address: PHILIPS ELECTRONICS NORTH AMERICA CORPORATION, INTELLECTUAL PROPERTY & STANDARDS, 1109 MCKAY DRIVE, M/S-41SJ, SAN JOSE, CA, 95131, US

(73) Assignee: KONINKLIJKE PHILIPS ELECTRONICS N.V.

(21) Appl. No.: 10/277,461

(22) Filed: Oct. 22, 2002

(51) Int. Cl. H01L 21/3205; H01L 21/4763

(52) U.S. Cl. 438/585; 438/952

(57) ABSTRACT

The invention relates to a method of adjusting the critical dimensions of a poly-silicon or amorphous silicon gate in an MOS transistor structure. In an example embodiment, there is a method for controlling critical dimensions on a wafer substrate, the wafer substrate comprising a silicon layer, an oxide layer, a poly-silicon layer, and an organic bottom anti-reflective coating (BARC) layer. The method comprises defining features on the organic BARC layer with a masking layer, the features having masking critical dimensions. With a first etch, unmasked areas on the organic BARC layer are etched until the poly-silicon layer is exposed. The first etch defines after-etch critical dimensions of the features.

### FIELD OF THE INVENTION

The invention relates to semiconductor process. More particularly the invention relates to critical dimension (CD) control of printed features on a wafer substrate.

### BACKGROUND

The electronics industry continues to rely upon advances in semiconductor technology to realized higher-function devices in more compact areas. For many applications, realizing higher-functioning devices requires integrating a large number of electronic devices into a single silicon wafer. As the number of electronic devices per given area of the silicon wafer increases, the manufacturing process becomes more difficult.

A large variety of semiconductor devices has been manufactured having various applications in numerous disciplines. Such silicon-based semiconductor devices often include metal-oxide-semiconductor (MOS) transistors, such as p-channel MOS (PMOS), n-channel MOS (NMOS) and complementary MOS (CMOS) transistors, bipolar transistors, BiCMOS transistors.

Each of these semiconductor devices generally includes a semiconductor substrate on which a number of active devices are formed. The particular structure of a given active device can vary between device types. For example, in MOS transistors, an active device generally includes source and drain regions and a gate electrode that modulates current between the source and drain regions.

One important step in the manufacturing of such devices is the formation of devices, or portions thereof, using photolithography and etching processes. In photolithography, a wafer substrate is coated with a light-sensitive material called photo-resist. Next, the wafer is exposed to light; the light striking the wafer is passed through a mask plate. This mask plate defines the desired features to be printed on the substrate. After exposure, the resist-coated wafer substrate is developed. The desired features as defined on the mask are retained on the photo resist-coated substrate. Unexposed areas of resist are washed away with a developer. The wafer having the desired features defined is subjected to etching. Depending upon the production process, the etching may either be a wet etch, in which liquid chemicals are used to remove wafer material or a dry etch, in which wafer material is subjected to a radio frequency (RF) induced plasma.

Often desired features have particular regions in which the final printed and etched regions have to be accurately reproduced over time. These are referred to as critical dimensions (CDs). As device geometry approaches the sub-micron realm, wafer fabrication becomes more reliant on maintaining consistent CDs over normal process variations. The active device dimensions as designed and replicated on the photo mask and those actually rendered on the wafer substrate have to be repeatable and controllable. In many situations, the process attempts to maintain the final CDs equal to the masking CDs. However, imperfections in the process or changes in technology (that may be realized in a given fabrication process, if the process were “tweaked”) often necessitate the rendering of final CDs that deviate from the masking CDs.

### SUMMARY OF THE INVENTION

There is a need for a photolithographic process that enables the user to adjust the final CDs in features printed on a wafer substrate that deviate from the masking CDs. In an example embodiment, there is a method for controlling critical dimensions on a wafer substrate, the wafer substrate comprising a silicon layer, an oxide layer, a poly-silicon layer, and an organic bottom anti-reflective coating (BARC) layer. The method comprises defining features on the organic BARC layer with a masking layer, the features having masking critical dimensions. With a first etch, unmasked areas on the organic BARC layer are etched until the poly-silicon layer is exposed. The first etch defines after-etch critical dimensions of the features. A feature of this embodiment is that the first etch may be selected to bias the after-etch critical dimensions in either a positive direction or a negative direction.

In another example embodiment, there is a method for adjusting critical dimensions on a poly-silicon gate structure. The gate structure comprises a silicon substrate, an oxide layer, a poly-silicon layer, and a BARC layer. The method comprises defining features that have printed critical dimensions, on the BARC layer of the poly-silicon gate structure with a mask layer. The mask layer has critical dimensions. With an etch to adjust the printed critical dimensions, the BARC layer is etched with an etch. The etch is comprised of at least one of the two etches. A first BARC etch biases the printed critical dimensions greater than the mask layer critical dimensions. A second BARC etch biases the printed critical dimensions less than the mask layer critical dimensions.

The above summaries of the present invention are not intended to represent each disclosed embodiment, or every aspect, of the present invention. Other aspects and example embodiments are provided in the figures and the detailed description that follows.

### BRIEF DESCRIPTION OF THE DRAWINGS

The invention may be more completely understood in consideration of the following detailed description of various embodiments of the invention in connection with the accompanying drawings, in which:

FIG. 1 is a flowchart outlining the process according to an embodiment of the present invention;

FIG. 1A is a flowchart outlining the process of FIG. 1 with a focus on the etching of the BARC layer for CD adjust;

FIG. 2A illustrates a cross-section of a substrate to be processed according to an embodiment of the present invention;

FIG. 2B illustrates the cross-section of FIG. 2A with a mask having features with a critical dimension (CD);

FIG. 2C illustrates the enlarging of an after etch CD with respect to the mask CD according to an embodiment of the present invention;

FIG. 2D illustrates the reducing of a after etch CD with respect to the mask CD according to another embodiment of the present invention;

FIG. 2E illustrates a final CD with respect to the mask CD after the removal of the masking layer and BARC layer of FIG. 2C;

FIG. 3A is a plot of Pre-Etch and Post-Etch CDs and the Δ Pre/Post Etch CD with a first BARC etch chemistry according to the present invention;

FIG. 3B is a plot of Pre-Etch, Post Etch CDs v. Increased Overetch with a second BARC etch chemistry according to the present invention; and

FIG. 3C is a plot of ΔCD v. Overetch Time with a combination chemistry of the first BARC etch chemistry and the second BARC etch chemistry according to the present invention.

### DETAILED DESCRIPTION

The present invention has been found to be useful in the rendering of final CDs that differ from those on the photo mask. The present invention has been found to be particularly useful in situations in which changes in fabrication processes result in CD changes make it not cost-effective to replace photo masks in response to those changes.

An organic BARC (Bottom Anti-Reflective Coating) is applied to a wafer substrate upon which poly-silicon or amorphous silicon (α-silicon) has been deposited. The features to be printed are masked. The mask has particular CDs to be rendered onto the poly-silicon. The wafer substrate is plasma etched for a predetermined time. The type of etch depends upon which direction the final CDs are biased, either up or down in relation to the mask CDs. During plasma etch, the gases react with photo resist and other compounds on the wafers to form long molecular chains (polymers) containing carbon, hydrogen, and other elements. These polymers deposit on the sidewall of the poly-silicon lines being etched. Depending upon the type of gases used in the reaction, these polymer chains are either formed or are removed. Organic BARC is applied like photo resist, with a spin-on process. There are different organic BARC formulations supplied by different vendors, but essentially they have the same optical and etch properties. Similar etch chemistries will etch them all.

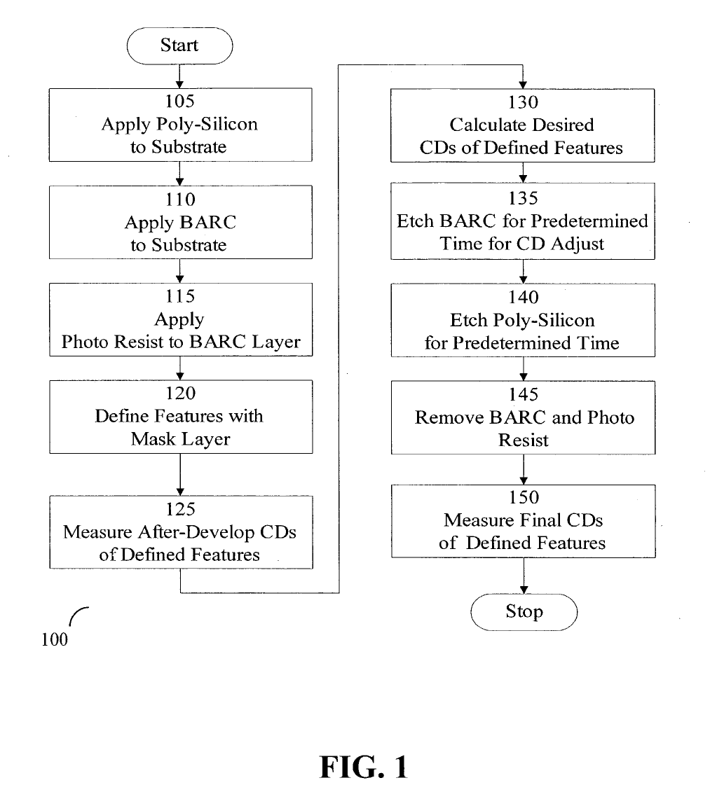

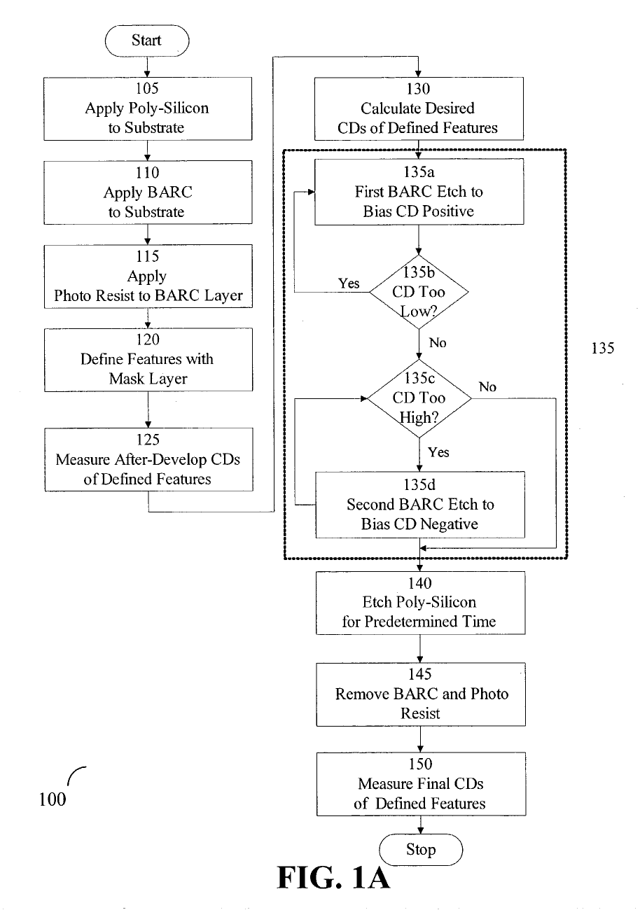

Refer to FIG. 1. In an example process according to the present invention, there is a process 100. On a silicon substrate, upon which a thin dielectric is applied (usually a silicon oxide), poly-silicon (or α-silicon) is applied to the substrate 105. A BARC layer is applied on the poly-silicon 110. Next, photo resist is applied onto the BARC layer 115. With a mask layer, the features are defined 120. Usually, the photo resist coated wafer substrate is loaded into a wafer stepper and the features of a photo mask are printed thereon. The wafer substrate is developed to render the features to be etched. Often, as a means of monitoring process quality, the user measures the CDs of the defined features 125 after the photo resist is developed. The desired CDs of the defined features are calculated 130. For the CD adjust 135, the BARC layer is etched for a predetermined time. After BARC etch, the poly-silicon is etched for another predetermined time 140. The BARC and resist is removed 145. For measuring process quality, the final CDs may be measured 150.

In an example embodiment according to the present invention, the CDs may be adjusted upward (i.e., a positive bias) with a first etch.

In another example embodiment according to the present invention, the CDs may be adjusted downward (i.e., a negative bias) with a second etch. Refer to FIG. 1A. Details of the BARC etch are shown in step 135. A first BARC etch is used to bias the CD in a positive direction 135a. If the CD is too low 135b, the etch may continue. If at desired CD, the process verifies whether the CD is too high 135c. If too high, a second BARC etch is used to bias the CD in the negative direction 135d. Process resumes to that illustrated in FIG. 1. Some example CD etch processes are illustrated in tables that follow.

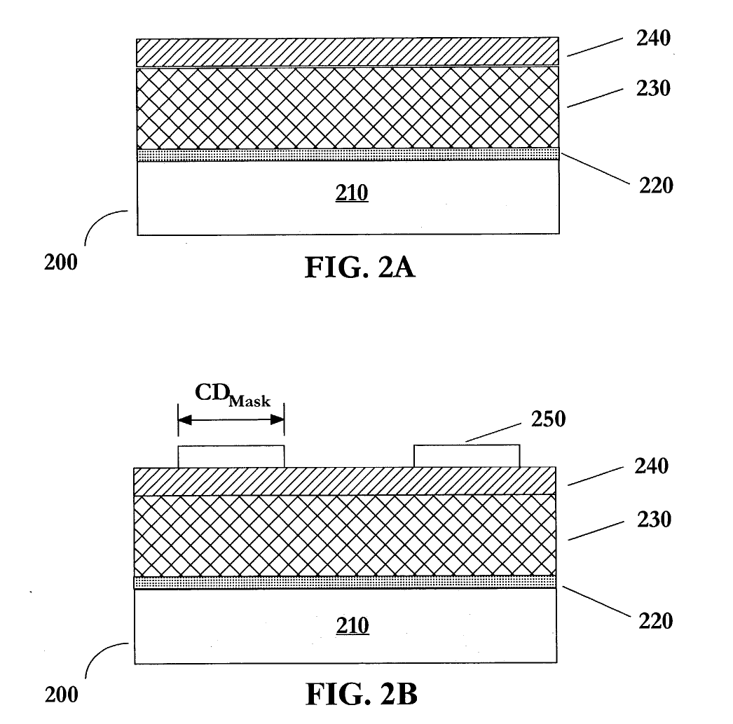

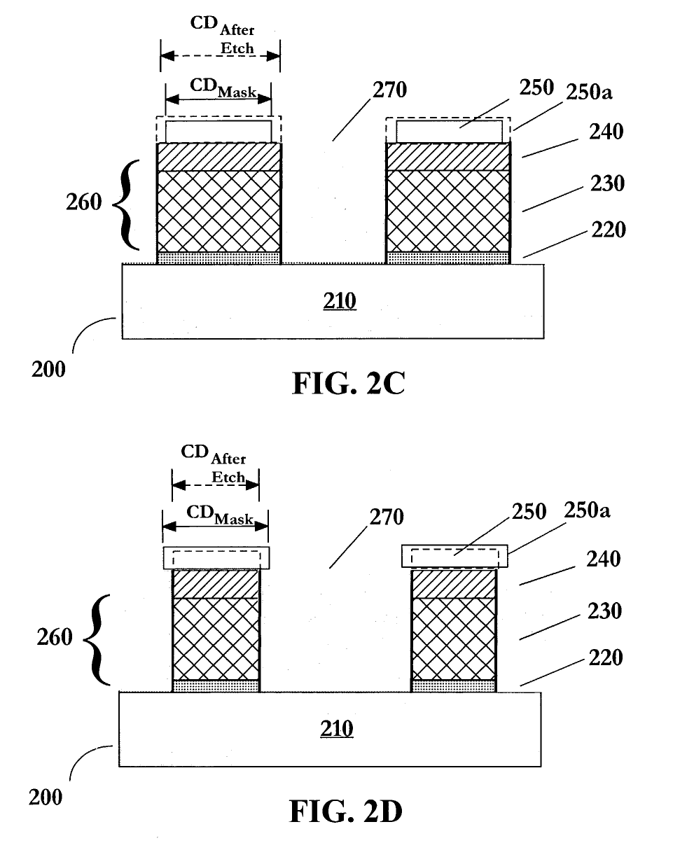

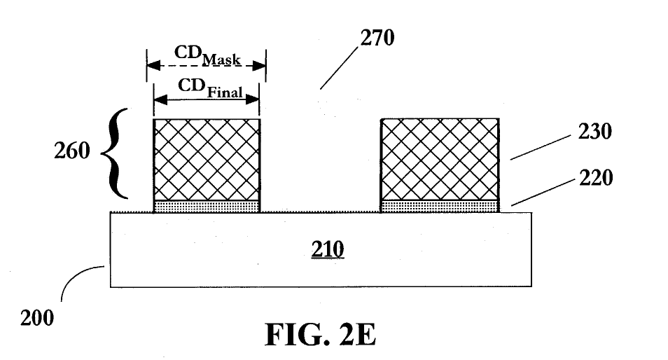

A series of figures, illustrates the process according to the present invention. The gate of an MOS transistor is being defined. Refer to FIG. 2A. A substrate 200 has a silicon layer 210. Upon the silicon layer 210, there is a dielectric layer 220, usually an oxide. Upon the dielectric layer 220, poly or (α-silicon) is applied 230. The BARC layer 240 is on the poly-silicon layer 230. The critical dimensions involve the poly-silicon gate of an example MOS transistor that is fabricated.

Refer to FIG. 2B. A mask layer 250 is applied to the BARC layer 240. The mask layer has and example critical dimension, so labeled as CD_{Mask}. The process 100 of FIG. 1 etches the BARC layer 240, poly-silicon layer 230, and dielectric layer 220. These layers from a stack 260. Depending upon the bias of the etch process, the profiles of either FIG. 2C or FIG. 2D are attained.

Refer to FIG. 2C. The unmasked areas 270 have the stack 260 removed. In that the bias is positive, the final feature size 250a is greater than the mask feature size 250. CD_{After Etch} is greater than CD_{Mask}. The CD_{After Etch} features are depicted with dashed lines.

Refer to FIG. 2D. Refer to FIG. 2C. The unmasked areas 270 have the stack 260 removed. In that the bias is negative, the final feature size 250a is less than the mask feature size 250. CD_{After Etch} is less than CD_{Mask}. Again, the CD_{After Etch} features are depicted with dashed lines. After the desired after etch CD is obtained, the photo resist layer 250 and organic BARC layer 240 are removed. The final critical dimension of etch, CD_{Final} may or may not be equal to the CD_{After Etch}. However, this difference may be characterized for the given fabrication process.

Refer to FIG. 2E. The mask layer 250 and the BARC layer 240 are removed. The substrate 200 has the remaining features of a poly silicon layer 230 over a thin oxide layer 220. In an example process, these features define the gate regions of a MOS transistor. The CD_{Final} measurements of the gate regions are taken after the process removes the photo resist and BARC layer that defined them.

Refer to Table 1. To increase the CDs, the substrate undergoes CF₄ etch. The substrate is placed into a plasma etch apparatus. The reactant gas CF₄ is released into the chamber at about 7 m Torr. After 30 seconds at Step 1, the etch begins and proceeds until a fixed time or endpoint is reached. The fixed time or endpoint would be determined by the process parameters particular to a given manufacturing environment. The CDs are adjusted upward by the over etch of the BARC. The time T1 to produce the required CDs is characterized for a given fabrication process.

TABLE 1
First Recipe to Increase CDs

| 1st Recipe | Gas | | |
|---|---|---|---|
| CD Increase | stability | Etch | Over Etch |
| Step | Step 1 | Step 2 | Step 3 |
| Pressure (mTorr) | 7 | 7 | 7 |
| RF_Upper (W) | 0 | 250 | 250 |
| RF_Lower (W) | 3 | 170 | 170 |
| Gap (cm) | 6.03 | 8.1 | 8.1 |
| Cl2 (sccm) | 0 | 0 | 0 |
| He/O₂ (sccm) | 0 | 0 | 0 |
| HBr (sccm) | 0 | 0 | 0 |
| O₂ (sccm) | 0 | 0 | 10 |
| He | | | |
| CF₄ | 100 | 100 | 100 |
| SF₆ | | | |
| He-Clamp | 8 | | |
| Completion | Stabilize | Fixed Time | % |
| | | or Endpoint | Overetch |
| Time (sec) | 30 | | T1 |

Refer to Table 2. To decrease the CDs, the substrate undergoes an etch in HBr and O₂. The substrate is placed into a plasma etch apparatus. The reactant gas is released into the chamber at about 7 m Torr. After 30 seconds at Step 1, the etch begins and proceeds until a fixed time or endpoint is reached. The fixed time or endpoint would be determined by the process parameters particular to a given manufacturing environment. The CDs are adjusted downward by the over etch of the BARC. The time T2 to produce the required CDs would be characterized for a given fabrication process.

TABLE 2
Second Recipe to Decrease CDs

| 2nd Recipe | Gas | | |
|---|---|---|---|
| CD Reduction | stability | Etch | Over Etch |
| Step | Step 1 | Step 2 | Step 3 |
| Pressure (mTorr) | 7 | 7 | 7 |
| RF_Upper (W) | 0 | 250 | 250 |
| RF_Lower (W) | 0 | 140 | 140 |
| Gap (cm) | 6.03 | 8.1 | 8.1 |
| Cl₂ (sccm) | 0 | 0 | 0 |
| He/O₂ (sccm) | 0 | 0 | 0 |
| HBr (sccm) | 20 | 20 | 20 |
| O₂ (sccm) | 20 | 20 | 20 |
| He | 0 | 0 | 0 |
| CF₄ | 0 | 0 | 0 |
| SF₆ | | | |
| He-Clamp | 8 | 8 | 8 |
| Completion | Stabilize | Fixed Time | % |
| | | or Endpoint | Overetch |
| Time (sec) | 30 | | T2 |

Refer to Table 3. Rather than have separate etches for increasing the CDs and decreasing CDs, the two etches may be combined into a single process. The first etch increases the CDs for a predetermined time, T1. After the first etch, the second etch “dials” in the desired CDs for a second predetermined time, T2. By printing and etching test wafers, T1 and T2 may be characterized. The test wafers have equivalent CD features similar to those used in product wafers having integrated circuit devices. Results of the characterization enables the user to derive a particular T1 and T2 for a given fabrication process.

TABLE 3
Combination Recipe to Dial in CDs

| Combo Recipe | Gas | First | Gas | Second |
|---|---|---|---|---|
| CD Dial-In | stability | Etch | stability | Etch |
| Step | Step 1 | Step 2 | Step 3 | Step 3 |
| Pressure (mTorr) | 7 | 7 | 7 | 7 |
| RF_Upper (W) | 0 | 250 | 0 | 250 |
| RF_Lower (W) | 3 | 170 | 0 | 140 |
| Gap (cm) | 6.03 | 8.1 | 8.1 | 8.1 |
| Cl₂ (sccm) | 0 | 0 | 0 | 0 |
| He/O₂ (sccm) | 0 | 0 | 0 | 0 |
| HBr (sccm) | 0 | 0 | 20 | 20 |
| O₂ (sccm) | 0 | 0 | 20 | 20 |
| He | 0 | 0 | 0 | 0 |
| CF₄ | 100 | 100 | 0 | 0 |
| SF₆ | | | | |
| He-Clamp | 8 | 8 | 8 | 8 |
| Completion | Stabilize | Fixed Time | Stabilize | % |
| | | or Endpoint | | Overetch |
| Time (sec) | 30 | T1 | 30 | T2 |

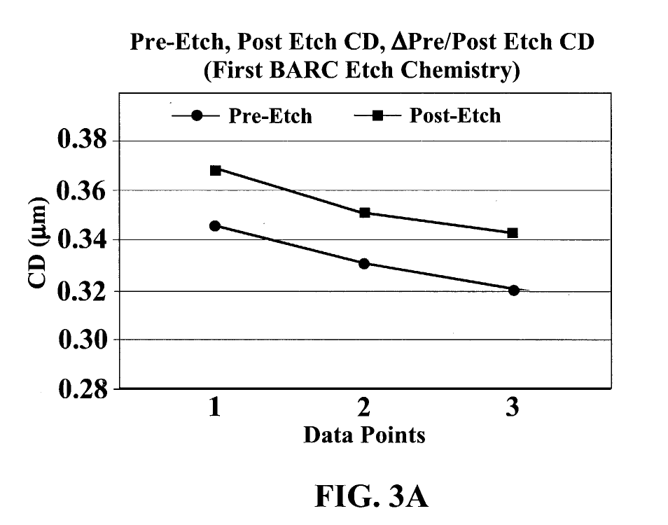

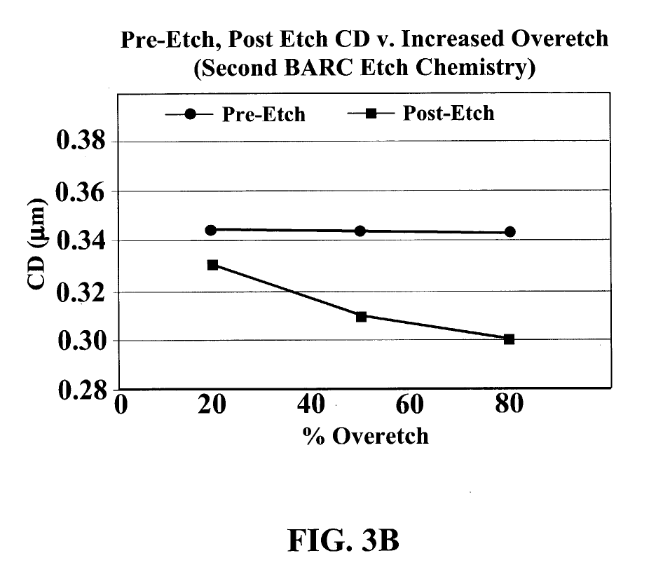

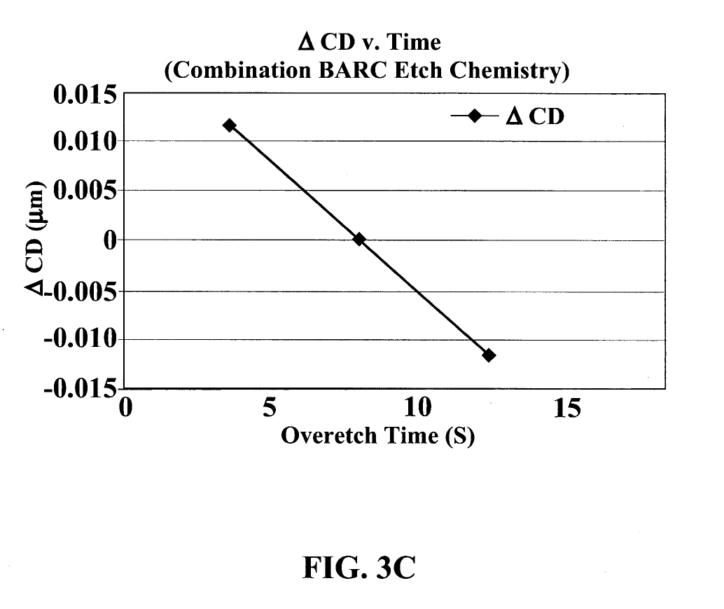

Refer to FIG. 3A. In an example process, with a first BARC etch chemistry, the pre-etch and post-etch critical dimensions (CDs) along with their corresponding differences have been characterized and are plotted. The etch time had been fixed to ensure complete removal of the BARC with the first recipe. In this process, the post etch CDs are greater than the pre-etch CDs. For the three sample data points, the difference between the pre etch and post-etch is about constant, about 0.02 μm. In a production process, many more data points are collected and analyzed. In an example manufacturing process, these data points may range into the hundreds over many wafer substrates processed over several weeks.

Refer to FIG. 3B. In another example process, with a second BARC etch chemistry, the pre-etch and post-etch critical dimensions (CDs) along with their corresponding differences are plotted. However, unlike that depicted in FIG. 3A, in which BARC was completely removed, FIG. 3B shows the differences plotted against the percentage of over etch. The second etch decreases the post-etch CDs. For a 20% over etch, the difference between the pre and post-etch CD is about −0.015 μm. For an 80% over etch, the difference is about −0.045 μm.

In yet another recipe according to an embodiment of the present invention, the recipes as depicted in Tables 1 and 2 and then combined in Table 3 may be characterized and plotted. Refer to FIG. 3C. The plot depicts the CD Change (ΔCD) v. Time. To derive this plot, the etch time for the first recipe was at a fixed T1. With the second recipe, the etch time T2 was varied. Thus, the increased CD_{After Etch} of about 0.012 μm is reduced to CD_{Mask} (ΔCD=0) and CD_{After Etch}=CD_{Mask}, after about 7 seconds. After about 12 seconds, the CD_{After Etch} is about −0.012 μm less than CD_{Mask}. Of course, other plots may be derived depending upon particular process characteristics in a manufacturing environment.

While the present invention has been described with reference to several particular example embodiments, those skilled in the art will recognize that many changes may be made thereto without departing from the spirit and scope of the present invention, which is set forth in the following claims.

What is claimed:

1. A method for controlling critical dimensions on a wafer substrate, the wafer substrate comprising a silicon layer, an oxide layer, a poly-silicon layer, and an organic bottom anti-reflective coating (BARC) layer, the method comprising:
defining features on the organic BARC layer with a masking layer, the features having masking critical dimensions; and
etching with a first etch, unmasked area on the organic BARC layer until the poly-silicon layer is exposed, the first etch defining after-etch critical dimensions of the features.

2. The method of claim 1 wherein, the first etch is selected to bias the after-etch critical dimension by one of the following:
a positive direction; and
a negative direction.

3. The method of claim 2 wherein the first etch is a positive direction etch, the positive direction etch selected from the following: a fluorine containing etch and CF₄.

4. The method of claim 2 wherein the first etch is a negative direction etch, the negative direction etch selected from the following: an oxygen and bromine containing etch and HBr+O₂.

5. A method for manufacturing MOS transistor structure on a wafer substrate, the method comprising:
applying an oxide layer;
applying a layer of poly-silicon on the oxide layer;
applying a BARC layer on the poly-silicon;
applying a photo resist on the BARC layer;
defining features with a mask layer, the mask layer having mask critical dimensions (CDs);
measuring the critical dimensions after the photo-resist undergoes developing;
calculating the desired critical dimensions (CDs) of the features;
etching with a BARC etch, unmasked areas of the BARC layer for a predetermined time, the predetermined time is derived from the desired critical dimensions of the features;
etching, with a poly etch, the unmasked areas of poly-silicon, until oxide layer is exposed;
removing the photo resist and the BARC layer; and
measuring final critical dimensions of the features.

6. The method of claim 5, wherein the BARC etch comprises, at least one of the following:
a positive bias etch if the mask critical dimensions are less than the desired critical dimensions; and
a negative bias etch if the mask critical dimensions are greater than the desired critical dimensions.

7. The method of claim 6, wherein:
the positive bias etch comprises CF₄.
the negative bias etch comprises HBr+O₂.

8. The method of claim 6 wherein the BARC etch comprises a combination etch, the combination etch comprising:
etching the BARC with a positive bias etch for a T1; and
etching the BARC with a negative bias etch for a T2.

9. The method of claim 8 wherein the T1 and T2 are determined through a characterization of wafer substrate test wafers having critical dimensions defined thereon, the characterization resulting in a relationship of the desired CDs v. BARC etch time.

10. A method for adjusting critical dimensions on a poly-silicon gate structure, the gate structure comprising a silicon substrate, an oxide layer, a poly-silicon layer, and a BARC layer, the method comprising:
defining features, having printed critical dimensions, on the BARC layer of the poly-silicon gate structure with a mask layer, the mask layer having critical dimensions;
etching the BARC layer with an etch to adjust the printed critical dimensions, wherein the etch comprises, at least one of the following:
a first BARC etch to bias the printed critical dimensions greater than the mask layer critical dimensions; and
a second BARC etch to bias the printed critical dimensions less than the mask layer critical dimensions.
